(19) United States
(12) Patent Application Publication
(10) Pub. No.: US 2020/0255930 A1
(43) Pub. Date: Aug. 13, 2020

(54) ELECTRON BEAM ICE LITHOGRAPHY FOR FABRICATING 3D NANOSTRUCTURES

(71) Applicant: ZHEJIANG UNIVERSITY, Hangzhou (CN)

(72) Inventors: Min QIU, Hangzhou (CN); Ding ZHAO, Hangzhou (CN); Yu HONG, Hangzhou (CN); Dongli LIU, Hangzhou (CN)

(73) Assignee: ZHEJIANG UNIVERSITY

(21) Appl. No.: 16/270,170

(22) Filed: Feb. 7, 2019

(51) Int. Cl. C23C 14/04; H01J 37/317; C23C 16/04

(52) U.S. Cl. CPC C23C 14/042; C23C 16/042; H01J 37/3174

(57) ABSTRACT

The present invention relates to methods of electron beam lithography using ice resist to fabricate nanostructures on a substrate and, more particularly, to a method of fabricating desired three-dimensional nanostructures on a substrate. The method involves two main strategies: grayscale ice lithography and stacking layered structures. Moreover, these two strategies can be combined in one fabrication process to produce more complex 3D nanostructures.

### FIELD OF THE INVENTION

The present invention relates to methods of electron beam lithography using ice resist to fabricate nanostructures on a substrate and, more particularly, to a method of fabricating desired three-dimensional nanostructures on a substrate.

### BACKGROUND TECHNOLOGY

Three-dimensional (3D) functional materials and 3D nanostructures are widely used in nanophotonics, electronics, bionics, biomedical engineering, and energy engineering. However, electron-beam lithography (EBL, or E-beam lithography), as one of the most critical tools for nanofabrication, does not work well in fabricating 3D nanostructures. Conventionally, 3D nanofabrication using EBL is realized by stacking layered structures, in which each layer obtained through repeating a standard spin-coating-lithography-developing-deposition (or etching)-lift-off processes. It takes relatively longer overall fabrication time, especially for complex 3D nanostructures. The overlay alignment is typically realized through alignment masks, and the overall procedures are tedious, expensive and difficult to master.

E-beam lithography using ice resists (iEBL), also called electron beam ice lithography (EBIL), as a modified EBL technique, has emerged for nanofabrication with higher resolution, even on nonplanar and fragile substrates. In iEBL, the standard process is greatly simplified and streamlined by skipping spin-coating and developing steps. Notably, ice resists covering substrates maintains the shape of substrates or previously fabricated nanostructures, which can be clearly distinguished by SEM imaging. Attributing to the very low sensitivity of water ice, iEBL enables in situ alignment and correction with the previous layer. This feature is significantly beneficial to the improvement of overlay alignment accuracy. Moreover, ice is easily removed without leaving any residue by simply raising the temperature during the lift-off step, providing great potential to fabricate suspended or hollow structures. These and other advantages make iEBL an excellent candidate for 3D nanofabrication.

### SUMMARY OF THE INVENTION

There is provided a method for fabricating 3D nanostructures on a substrate by modified electron beam ice lithography. The method involves two main strategies: grayscale ice lithography and stacking layered structures. These two strategies can be combined in one fabrication process to produce more complex 3D nanostructures.

According to the method, water vapor is first deposited on a surface of a substrate to form an amorphous ice resist layer.

When applying the strategy of grayscale ice lithography, a grayscale scanning pattern is then determined based on the feature of the desired nanostructure and the substrate surface. This grayscale scanning pattern is written on the ice resist layer by E-beam to remove a portion of the ice resist layer and form a three-dimensional pattern in the ice resist layer. Subsequently, a material layer is deposited on the surface of the patterned region and on the top of the ice resist layer that is not exposed by the electron beam. Finally, the ice resist layer and the material layer on the top of the unexposed ice resist layer is removed, leaving a three-dimensional material nanostructure on the substrate.

When applying the strategy of stacking layered structures, a monochrome or grayscale scanning pattern is then written by E-beam on the ice resist layer to remove a portion of the ice resist layer. Then a material layer is deposited on the surface of the patterned region and on the top of the ice resist layer that is not exposed by the electron beam. Thereafter, the following steps are repeated: depositing a new layer of amorphous ice resist on the surface of previous materials layer, E-beam writing a monochrome or grayscale scanning pattern on the new ice resist layer and depositing a new material layer. These repeating steps finally form a hierarchical three-dimensional nanostructure surrounded by ice/material multilayers, which can be removed to reveal the hierarchical three-dimensional nanostructure on the substrate.

### BRIEF DESCRIPTION OF THE DRAWINGS

FIG. 1 is a flowchart illustrating an exemplary method for fabricating a 3D nanostructure on a surface of a substrate by the strategy of grayscale ice lithography.

FIGS. 2A-2E are cross-section side views of an exemplary substrate illustrating the steps the exemplary method shown in FIG. 1.

FIG. 3 is a grayscale scanning pattern of the exemplary method shown in FIG. 1.

FIG. 4 is a plot of measured contrast curve of ice resist.

FIG. 5 is a flowchart illustrating an exemplary method for fabricating a 3D nanostructure on a surface of a substrate by the strategy of stacking layered structures.

FIGS. 6A-6H are cross-section side views of an exemplary substrate illustrating the steps the exemplary method shown in FIG. 5.

FIGS. 7A-7D are cross-sectional side views of a further exemplary substrate illustrating stacking a material layer on a 3D nanostructure layer with the exemplary method shown in FIG. 5.

FIGS. 8A-8D are cross-sectional side views of a further exemplary substrate illustrating stacking a 3D nanostructure layer on a planar material layer with the exemplary method shown in FIG. 5.

### DETAILED DESCRIPTION OF THE EMBODIMENTS OF THE INVENTION

Although the present invention is illustrated and described herein with reference to specific embodiments, the present invention is not intended to be limited to the details shown. Rather, various modifications may be made in the details within the scope and range of equivalents of the claims and without departing from the invention.

A method for fabricating 3D nanostructures on a substrate by modified electron beam ice lithography is described herein. The method involves two main strategies: grayscale ice lithography and stacking layered structures. Moreover, these two strategies can be combined in one fabrication process to produce more complex 3D nanostructures.

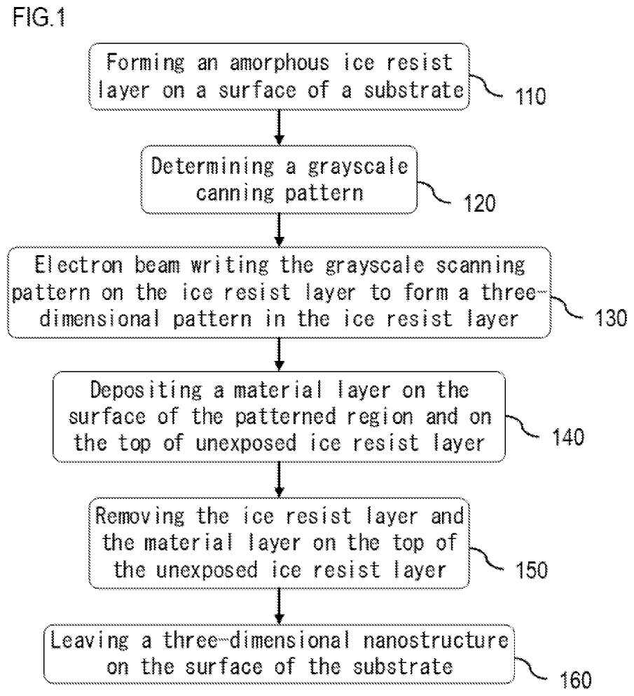

FIG. 1 is a flowchart illustrating an exemplary method for fabricating a 3D nanostructure on a surface of a substrate by the strategy of grayscale ice lithography.

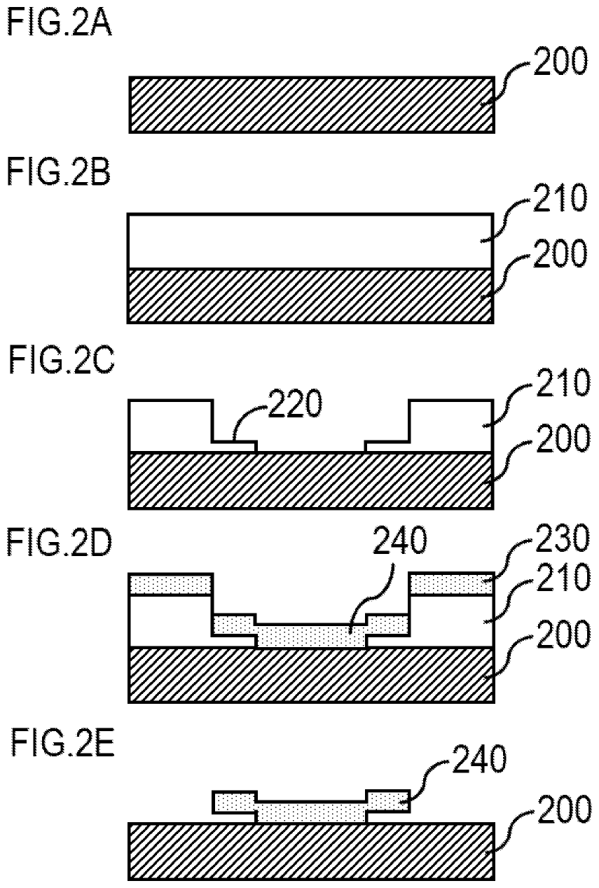

FIGS. 2A-2E are cross-section side views of an exemplary substrate illustrating the steps the exemplary method shown in FIG. 1.

Referring now to FIGS. 2A-2E, in exemplary embodiments of the present invention, a 3D nanostructure 240 on a substrate 200 may be realized, for example, by following steps:

a) depositing water vapor on the surface of the substrate 200 to form an amorphous ice resist layer 210;

b) determining a grayscale scanning pattern (as shown in FIG. 2) based on the feature of the desired 3D nanostructure 240 and the surface of the substrate 200;

c) electron beam writing the grayscale scanning pattern determined in step (b) on the ice resist layer 210 to remove a portion of the ice resist layer 210 and form a 3D pattern region 220 in the ice resist layer 210 and leaving remaining portion of the ice resist layer 210 unexposed to the electron beam (an unexposed portion);

d) depositing a material layer on a top surface of the ice resist layer 210, wherein the material is deposited on a top surface of the 3D patterned region 220 to form the 3D nanostructure 240, and the material is deposited on a top surface of the unexposed portion of the ice resist layer 210 to form an additional material portion 230; and

e) removing the ice resist layer 210, and removing the additional material portion 230, leaving a three-dimensional material nanostructure 240 on the substrate 200.

In step 110, the substrate 200 may be formed by any types of materials, such as metal, alloy, polymer, silicon, ceramic, glass, graphene, carbon nanotube, biomaterial, etc. The surface of the substrate 200 can be either planar or non-planar. The other detail of preparing water vapor and forming ice resist layer is referred to the process in typical iEBL, which is described in U.S. Pat. No. 8,790,863, issued on Jul. 29, 2014, which is incorporated by reference.

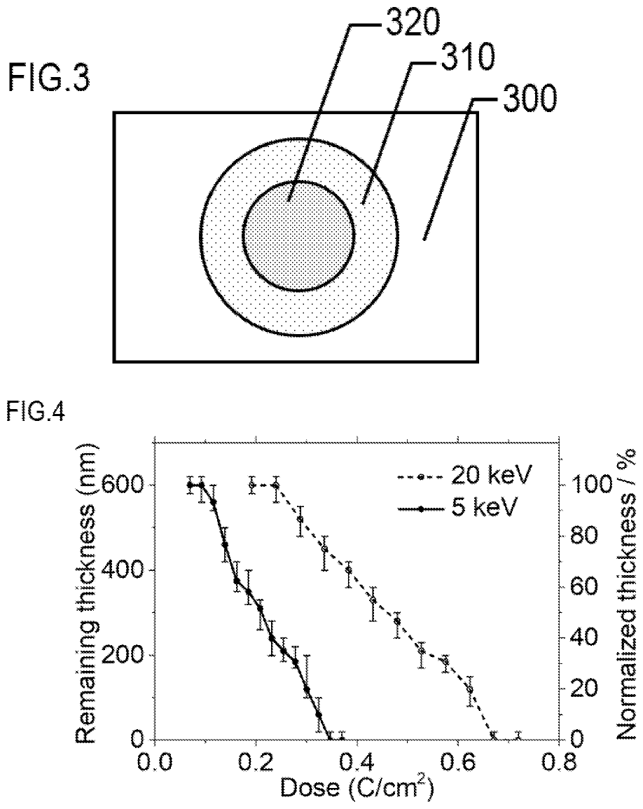

In step 120, the surface of the substrate 200 is profiled, especially when the substrate 200 has a non-planar surface. This operation may be performed by any contact or non-contact profilometry techniques, such as atomic force microscope, step profiler, etc. With the surface profile of the substrate 200, it is possible to design a desired thickness distribution of the remained ice resist layer after E-beam writing, which can be calculated into the electron beam dose distribution in grayscale scanning pattern (as shown in FIG. 3) with the contrast curve of ice resist (as shown in FIG. 4). In this exemplary embodiment, there are different E-beam dose distribution in three areas of the grayscale scanning pattern. An area 300 is subjected to no E-beam exposure. An area 310 is subjected to relatively low-dose E-beam exposure. An area 320 is subjected to relatively high-dose E-beam exposure. However, the number of different dose levels is not limited in this invention, and the E-beam exposure dose may even be continuously varied in different regions.

In step 130, the three-dimensional pattern 220 is formed by only once E-beam exposure. To facilitate the performance of step 150, it should be ensured that there is sufficient height difference at the edges of the 3D pattern 220 to avoid contact of the additional material portion 230 and the 3D nanostructure 240. The other detail of E-beam writing ice resist layer is referred to the process in typical iEBL, which is described in U.S. Pat. No. 8,790,863, issued on Jul. 29, 2014.

In step 140, the additional material portion 230 and the 3D nanostructure 240 may be formed by any types of materials, such as metal, alloy, dielectric, semiconductor, etc. Material deposition may be performed by any types of film deposition techniques, such as sputter deposition, vapor deposition, electrophoretic deposition, etc. The substrate 200 should be connected to a cold source to keep the temperature of the ice resist layer 210 from rising during material deposition, thereby avoiding melting or deformation of the 3D pattern 220. Other deposition process parameters can be referred to the general film deposition process.

In step 150, the ice resist layer 210 and the additional material portion 230 are removed by a process of lift-off, for example, by one of following methods: (1) immersing the substrate 200 with upper layers into solution, such as isopropanol, and the additional material portion 230 is rinsed as the ice resist layer 210 is melted; (2) warming the ice resist layer 210 and the additional material portion 230 in vacuum or atmosphere and blowing them away with airflow; or (3) warming the ice resist layer 210 and the additional material portion 230 in vacuum or atmosphere and pull them off with a sticky stamp.

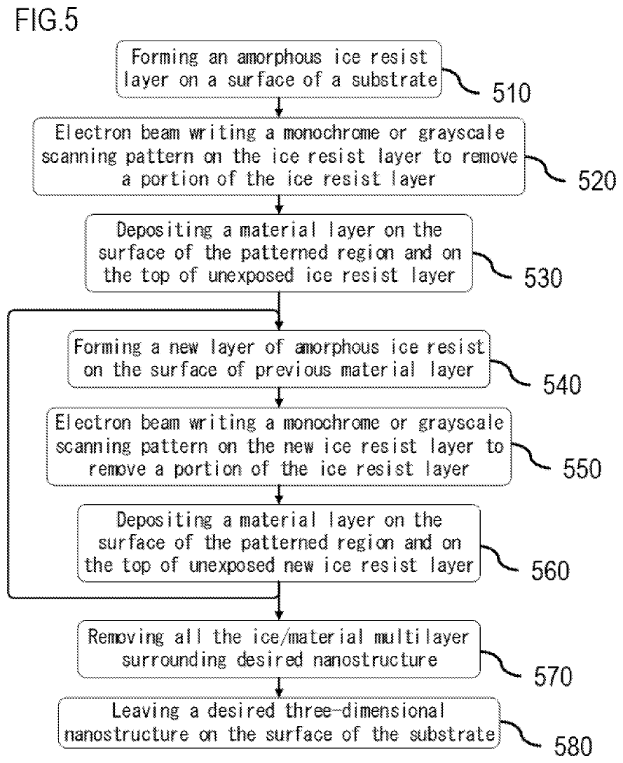

FIG. 5 is a flowchart illustrating an exemplary method for fabricating a 3D nanostructure on a surface of a substrate by the strategy of stacking layered structures.

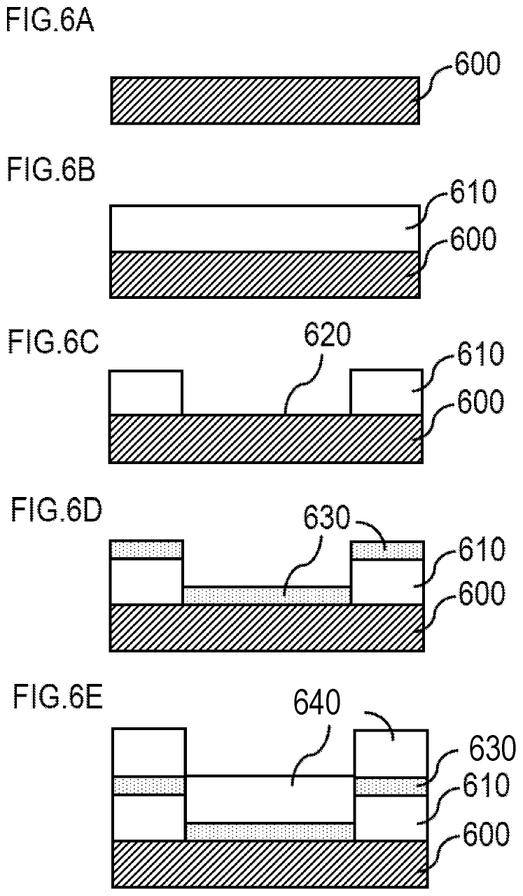

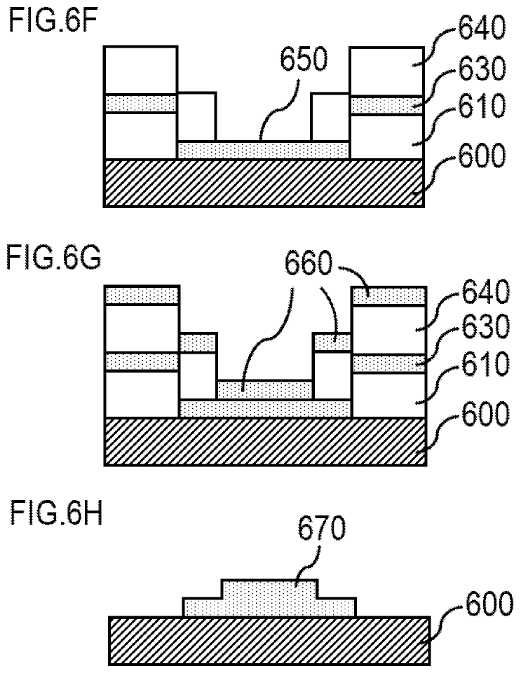

FIGS. 6A-6H are cross-section side views of an exemplary substrate illustrating the steps the exemplary method shown in FIG. 5.

Referring now to FIGS. 6A-6H, in exemplary embodiments of the present invention, a 3D nanostructure 670 on a substrate 600 may be realized, for example, by following steps:

a) depositing water vapor on the surface of the substrate 600 to form a first amorphous ice resist layer 610;

b) electron beam writing a pattern on the first ice resist layer 610 to remove a portion of the first ice resist layer 610, forming a first pattern 620 in the first ice resist layer 610;

c) depositing a first material layer 630 on the surface of the patterned region 620 and on the top surface of the first ice resist layer 610 where is not exposed by the electron beam.

d) depositing water vapor on the surface of the first material layer 630 to form a second amorphous ice resist layer 640;

e) electron beam writing a second pattern 650 on the second ice resist layer 640 formed in step (d) to remove a portion of the second ice resist layer 640, forming the second pattern 650 in the second ice resist layer 640;

f) depositing a second material layer 660 on the surface of the patterned region and on the top surface of the second ice resist layer 640 that is not exposed by the electron beam;

g) removing all the surrounding ice/material multilayers, leaving hierarchical three-dimensional nanostructure 670 on the substrate.

Considering from step 510 to step 530, the processing steps of ice forming, E-beam writing and material depositing are the same as that of typical iEBL and will not be further described here. More detail is referred to U.S. Pat. No. 8,790,863, issued on Jul. 29, 2014.

In step 540, instead of performing a lift-off step like typical iEBL, a new layer of ice resist (the second ice resist layer) 640 is deposited on the underneath material layer (the first material layer) 630 with the same way of step 510. The second ice resist layer 640 has the same surface profile as the second material layer 630.

In step 550, an image of the second ice resist layer 640 is produced by scanning electron beam along the surface of the first material layer 630 through the second ice resist layer 640. With this image, features in the first material layer 630 can be identified and viewed as an alignment mark for writing a second pattern 650 by electron beam on the second ice resist layer 640. A very low alignment error that is below 20 nm, therefore, can be achieved in a simple way.

In step 560, a new material layer (a second material layer) 660 is deposited in the same way of step 530.

From step 540 to step 560, a new layer of material is added and bonded to the material structure formed in step 530, forming an updated 3D structure. More individual layered structures can be added by repeating step 540 through step 560. Finally, a 3D hierarchical nanostructure 670 surrounded by ice/material multilayers is produced on the surface of substrate 600.

In step 570, all ice/material layers are removed by only one lift-off step no matter how many layers the three-dimensional hierarchical nanostructure contains. This avoids the time cost and possible contamination caused by the lift-off operation after each deposition of a material layer in conventional electron beam lithography processing. The process of lift-off in step 570 is the same as in step 150.

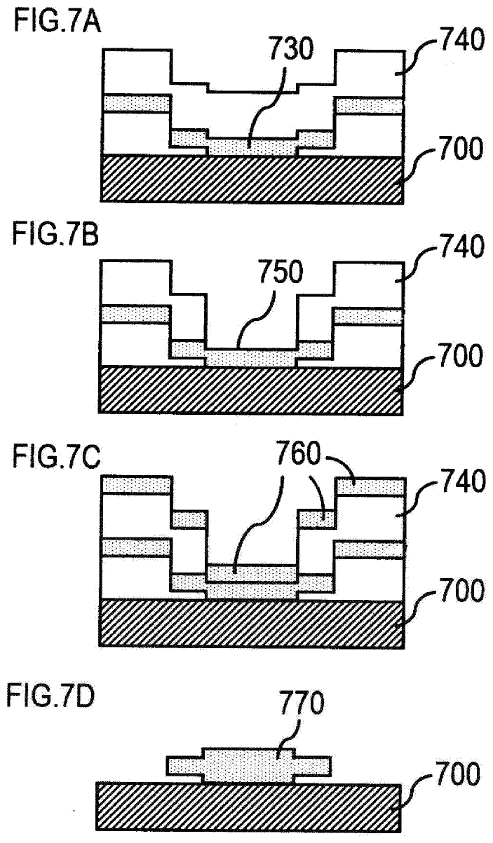

In step 520, optionally, a grayscale scanning pattern may be written on the ice resist to produce a 3D nanostructure in the subsequent processing steps. Then, a more complex 3D nanostructure can be produced by stacking layered structures on this 3D nanostructure layer, which is realized in step 540 to step 580. FIGS. 7A-7D are cross-sectional side views of an exemplary substrate showing step 540 to step 580 of the exemplary method in this case.

Referring now to FIGS. 7A-7D, after a 3D nanostructure layer 730 being produced on a substrate 700 by grayscale ice lithography, a new (second) ice resist layer 740 is deposited. A monochrome scanning pattern is then written on the new ice resist layer 740, forming a pattern 750 in the new ice resist layer 740. After depositing a material layer 760 and removing the surrounding ice/material multilayers, a complex 3D nanostructure 770 is finally fabricated on the substrate 700.

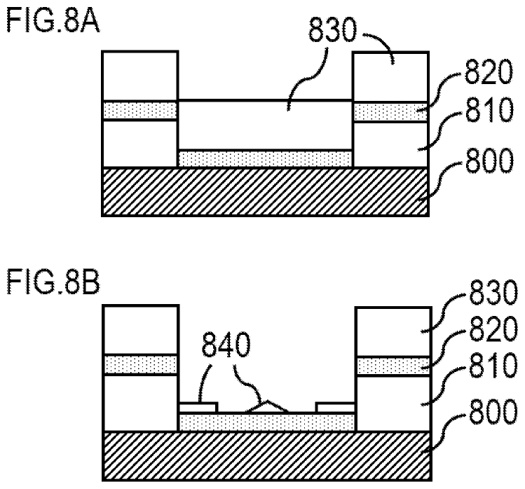

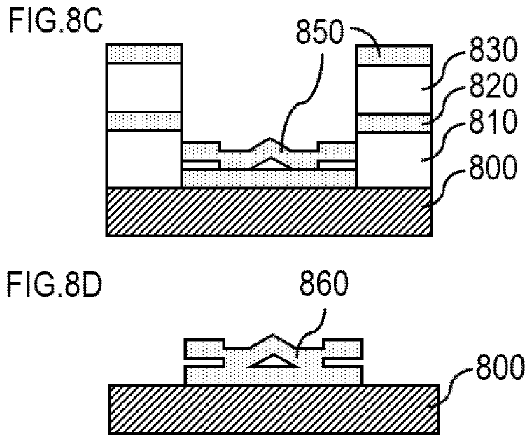

In addition, also in step 550, a grayscale scanning pattern may be written on the ice resist to produce a 3D nanostructure layer stacked on previous planar material layer. FIGS. 8A-8D are cross-sectional side views of an exemplary substrate showing step 540 to step 580 of the exemplary method in this case.

Referring now to FIGS. 8A-8D, depositing water vapor on the surface of the substrate 800 to form a first amorphous ice resist layer 810, after depositing a second ice resist layer 830 on a first material layer 820, a grayscale scanning pattern is written on the second ice resist layer 830, forming a 3D pattern 840 in the second ice resist layer 830. After depositing a second material layer 850 and removing the surrounding ice/material multilayers, a complex 3D nanostructure 860 is finally fabricated on substrate 800.

It is recognized, of course, that those skilled in the art may make various modifications and additions to the processes of the invention without departing from the spirit and scope of the present contribution to the art. Accordingly, it is to be understood that the protection sought to be afforded hereby should be deemed to extend to the subject matter of the claims and all equivalents thereof fairly within the scope of the invention.

1. A method of fabricating a three-dimensional nanostructure on a surface of a substrate, comprising the steps of:
a) depositing water vapor on the surface of the substrate to form an amorphous ice resist layer;
b) determining a grayscale scanning pattern based on the feature of desired nanostructure and the surface of the substrate;
c) electron beam writing the grayscale scanning pattern determined in step (b) on the ice resist layer and removing a portion of the ice resist layer concurrently to form a three-dimensional pattern in the ice resist layer;
d) depositing a material layer on a top surface of the patterned region and on a top surface of the ice resist layer that is not exposed to the electron beam; and
e) removing the ice resist layer and removing the material layer on the top surface of the ice resist layer that is not exposed to by the electron beam, leaving the three-dimensional material nanostructure on the substrate;
wherein the step (b) comprises the steps of:
b1) profiling the surface of the substrate;
b2) designing a desired thickness distribution of remained ice resist layer after E-beam writing; and
b3) calculating the electron beam dose distribution in the grayscale scanning pattern with a contrast curve of ice resist; and
wherein the dose range of the electron beam used to write the grayscale scanning pattern in the ice layer is 0-2 C/cm².

2. (canceled)

3. The method according to claim 1, wherein depositing the material layer in the step (d) by thermal evaporation or electron beam evaporation.

4. A method of fabricating a three-dimensional nanostructure on a surface of a substrate, comprising the steps of:
a) depositing water vapor on the surface of the substrate to form an amorphous first ice resist layer;
b) electron beam writing a first pattern on the first ice resist layer and removing a portion of the first ice resist layer concurrently to form a first patterned region;
c) depositing a first material layer on a top surface of the first patterned region and on a top surface of the first ice resist layer that is not exposed to the electron beam.
d) depositing water vapor on the surface of the first material layer to form an amorphous second ice resist layer;
e) electron beam writing a second pattern on the second ice resist layer formed in step (d) and removing a portion of the second ice resist layer concurrently to form a second patterned region;
f) depositing a second material layer on a top surface of the second patterned region and on a top surface of the second ice resist layer that is not exposed to the electron beam;
g) repeating the step (d) through the step (f) to form a hierarchical three-dimensional nanostructure surrounded by ice/material multilayers; and
h) removing the first and second ice resist layers and removing the first and second material layers on the surfaces of the first and second ice resists layers that are not exposed to the electron beam, leaving the hierarchical three-dimensional nanostructure on the substrate.

5. The method according to claim 4, wherein the step (b) further comprising electron beam writing a grayscale scanning pattern on the first ice resist layer and removing a portion of the first ice resist layer concurrently to form a first patterned region; and wherein the dose range of the electron beam used to write the grayscale scanning pattern in the ice layer is 0-2 C/cm².

6. The method according to claim 5 wherein the step (b) comprises the steps of:
b1) profiling the surface of the substrate;
b2) determining a desired thickness profile of remained ice resist layer after electron beam writing;
b3) calculating the electron beam dose distribution in the grayscale scanning pattern with a contrast curve of ice resist; and
b4) electron beam writing a grayscale pattern on the ice resist layer and removing a portion of the ice resist layer concurrently to form a three-dimensional pattern in the ice resist layer.

7. The method according to claim 4, wherein depositing the first material layer in the step (c) by thermal evaporation or electron beam evaporation, and depositing the second material layer in the step (f) by thermal evaporation or electron beam evaporation.

8. The method according to claim 4, wherein in the step (e) the second pattern is a three-dimensional grayscale scanning pattern, and wherein the dose range of the electron beam used to write the grayscale scanning pattern in the ice layer is 0-2 C/cm².

9. The method according to claim 8 wherein the step (e) comprises the steps of:
e1) profiling a surface of the second ice resist layer;
e2) designing a desired thickness distribution of the second ice resist layer after E-beam writing;
e3) calculating the electron beam dose distribution in grayscale scanning pattern with a contrast curve of ice resist; and
e4) electron beam writing a grayscale pattern on the second ice resist layer and removing a portion of the second ice resist layer concurrently to form the second three-dimensional pattern in the second ice resist layer.

10-11. (canceled)

12. A method of fabricating a three-dimensional nanostructure on a surface of a substrate, consisting of the steps of:
a) depositing water vapor on the surface of the substrate to form an amorphous ice resist layer;
b) determining a grayscale scanning pattern based on the feature of desired nanostructure and the surface of the substrate;
c) electron beam writing the grayscale scanning pattern determined in step (b) on the ice resist layer and removing a portion of the ice resist layer concurrently to form a three-dimensional pattern in the ice resist layer;
d) depositing a material layer on a top surface of the patterned region and on a top surface of the ice resist layer that is not exposed to the electron beam; and
e) removing the ice resist layer and removing the material layer on the top surface of the ice resist layer that is not exposed to by the electron beam, leaving the three-dimensional material nanostructure on the substrate;
wherein the step (b) consisting of the steps of:
b1) profiling the surface of the substrate;
b2) designing a desired thickness distribution of remained ice resist layer after E-beam writing; and
b3) calculating the electron beam dose distribution in the grayscale scanning pattern with a contrast curve of ice resist; and
wherein the dose range of the electron beam used to write the grayscale scanning pattern in the ice layer is 0-2 C/cm².
